(19) United States
(12) Patent Application Publication
(10) Pub. No.: US 2026/0231312 A1
(43) Pub. Date: Aug. 6, 2026

(54) TARGET MATERIAL STORAGE ASSEMBLY FOR AN EUV RADIATION SOURCE

(71) Applicant: ASML Netherlands B.V., Veldhoven (NL)

(72) Inventors: Rahul Sunil Kapadia, Eindhoven (NL); Pieter Gerardus Mathijs Hoeijmakers, Veldhoven (NL); Ivo Vanderhallen, Leende (NL)

(21) Appl. No.: 19/148,423

(22) PCT Filed: Jan. 11, 2024
(86) PCT No.: PCT/EP2024/050632

§ 371 Date: Jul. 16, 2025

Related U.S. Application Data
(60) Provisional application No. 63/441,288, filed on Jan. 26, 2023.

(51) Int. Cl. H05G 2/00; G03F 7/00

(52) U.S. Cl. CPC H05G 2/002; G03F 7/70033; H05G 2/008

(57) ABSTRACT

Disclosed is an apparatus adapted to store molten target material to be irradiated and converted in a source of extreme ultraviolet radiation in which a reservoir containing the molten target material is comprised of molybdenum fabricated so that the material properties of the molybdenum are isotropic, e.g., by using a hot isostatic pressing process.

### CROSS-REFERENCE TO RELATED APPLICATIONS

This application claims priority of U.S. Application No. 63/441,288, which was filed on Jan. 26, 2023, and which is incorporated herein in its entirety by reference.

### FIELD

The present disclosure relates to extreme ultraviolet radiation (“EUV”) sources that generate EUV radiation by converting a target material, in particular to devices and systems for storing the target material.

### BACKGROUND

EUV radiation, for example, electromagnetic radiation having a wavelength of around 50 nm or less (also sometimes referred to as soft x-rays) and including light at a wavelength of about 13 nm, is used in photolithography processes to produce extremely small features in and on substrates, for example, silicon wafers.

Methods for generating EUV radiation include, but are not limited to, those in which radiation is produced by first converting the physical state of a target material to a plasma state. The plasma is typically produced in a sealed vessel, for example, a vacuum chamber, and monitored using various types of metrology equipment. The target material includes an element, for example, xenon, lithium, or tin, with an emission line in the EUV range. The target material may be solid, liquid, or gaseous just prior to introduction into the vacuum chamber.

In one known method involving a liquid target material the necessary plasma is produced by irradiating a droplet or cluster of target material with a drive laser. One technique for generating droplets involves melting solid target material and then supplying the liquid target material to a droplet generator. The droplet generator forces the liquid target material under high pressure through a relatively small diameter orifice, such as an orifice having a diameter of about 0.5 μm to about 30 μm, to produce a stream of droplets. The droplet generator directs the droplets towards the primary focus of collector optics where at least some of the droplets are irradiated individually for EUV production.

In some systems the target material is stored in a target material storage system that includes one or more reservoirs. The reservoir holds the target material in reserve for ready supply to the droplet generator. The interior of the reservoir is maintained under pressure to force a flow of liquid target material from the reservoir to the droplet generator.

As mentioned, tin is one suitable choice for a target material. Hot molten tin, however, is extremely corrosive. Thus, components of the tin storage system such as the reservoir are made of a material that can withstand prolonged exposure to molten tin under pressure. Molybdenum (Mo) resists corrosion from exposure to molten tin which recommends it as a choice for a material for the reservoir. Care is needed, however, to ensure that techniques used in the manufacture of the storage systems do not compromise the mechanical qualities of the resulting molybdenum products. It would be advantageous to be able to make the reservoir out of a material that exhibits a corrosion resistance similar to that of molybdenum formed with standard techniques, but with simplified manufacture methods suitable for preserving or improving the material's mechanical properties.

It is in this context that the need for and advantages of the presently disclosed subject matter arise.

### SUMMARY

The following is a concise summary providing a basic understanding of the embodiments. This summary is not intended to be a comprehensive overview of all contemplated embodiments nor is it intended to identify as key or critical any elements of any embodiments. Its sole purpose is to present some concepts relating to one or more embodiments as a prelude to the more detailed description that is presented further below.

According to one aspect of an embodiment there is disclosed a target material storage system adapted to store a target material to be irradiated in an extreme ultraviolet radiation source, the target material storage system comprising a reservoir, the reservoir comprising substantially isotropic molybdenum. The substantially isotropic molybdenum may be made using a hot isostatic pressing process. The substantially isotropic molybdenum made using a hot isostatic pressing process is pure molybdenum. The substantially isotropic molybdenum made using a hot isostatic pressing process may be unalloyed molybdenum.

The target material storage system may further comprise a vessel cap arranged to seal an upper portion of the reservoir, wherein the vessel cap comprises substantially isotropic molybdenum. The vessel cap may comprise isotropic molybdenum made using a hot isostatic pressing process. The vessel cap may comprise pure isotropic molybdenum made using a hot isostatic pressing process. The vessel cap comprises unalloyed isotropic molybdenum made using a hot isostatic pressing process.

The target material storage system may further comprise a locking screw adapted to secure the vessel cap to the reservoir, with the locking screw comprising isotropic molybdenum. The locking screw may comprise isotropic molybdenum made using a hot isostatic pressing process. The locking screw may comprise pure isotropic molybdenum made using a hot isostatic pressing process. The locking screw may comprise unalloyed isotropic molybdenum made using a hot isostatic pressing process.

According to another aspect of an embodiment there is disclosed a molten tin storage system comprising at least one component which comes into contact with the molten tin, the at least one component comprising isotropic molybdenum. The isotropic molybdenum may be made using a hot isostatic pressing process. The isotropic molybdenum made using a hot isostatic pressing process may be unalloyed. The at least one component may comprise a reservoir defining a cavity adapted to contain the molten tin. The at least one component may further comprise a vessel cap arranged to seal an upper portion of the reservoir. The at least one component further may comprise a locking screw adapted to secure the vessel cap to the reservoir.

According to another aspect of an embodiment there is disclosed a source of extreme ultraviolet radiation for semiconductor photolithography, the source comprising a vacuum chamber, collector optics arranged within the vacuum chamber and to have a focus within the chamber, a target material delivery system arranged to dispense droplets of a target material to an irradiation site within the chamber at the focus, and a target material storage system arranged to provide the target material to the droplet generator, the target material storage system comprising a target material reservoir comprising isotropic molybdenum. The isotropic molybdenum may be pure and made using a hot isostatic pressing process. The target material storage system may further comprise a target material level sensing electrode extending into the target material reservoir and adapted to sense a level of target material in the target material reservoir.

Further embodiments, features, and advantages of the subject matter of the present disclosure, as well as the structure and operation of various embodiments, are described in detail below with reference to the accompanying drawings.

### BRIEF DESCRIPTION OF THE DRAWINGS

The accompanying drawings, which are incorporated herein and form part of the specification, illustrate the presently disclosed subject matter and, together with the description, further serve to explain the principles of the presently disclosed subject matter and to enable a person skilled in the relevant art(s) to make and use the presently disclosed subject matter.

FIG. 1 is a partially schematic functional block diagram of an overall broad conception for a laser-produced plasma EUV radiation source system such as might incorporate an aspect of an embodiment.

FIG. 2 is a perspective drawing of a target material storage system with some hidden elements shown by a broken line in accordance with an aspect of an embodiment.

FIG. 3 is a cross section of an upper portion of a target material storage system in accordance with an aspect of an embodiment.

FIGS. 4A and 4B are diagrams illustrating operation of a level sensor in a target material storage system in accordance with an aspect of an embodiment.

Further features and advantages of the disclosed apparatus, as well as the structure and operation of various embodiments of the disclosed apparatus, are described in detail below with reference to the accompanying drawings. The disclosed apparatus is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are described below with reference to the drawings, wherein like reference numerals are used to refer to like elements throughout. In the following description, for purposes of explanation, numerous specific details are set forth in order to promote a thorough understanding of multiple embodiments. It may be evident in some or all instances, however, that any embodiment described below can be practiced without adopting the specific design details described below.

In the description that follows and in the claims the terms “up,” “down,” “upper,” “lower,” “top,” “bottom,” “vertical,” “horizontal,” and like terms may be employed. These terms are intended to show relative orientation only and not any orientation with respect to gravity unless otherwise indicated or clear from context.

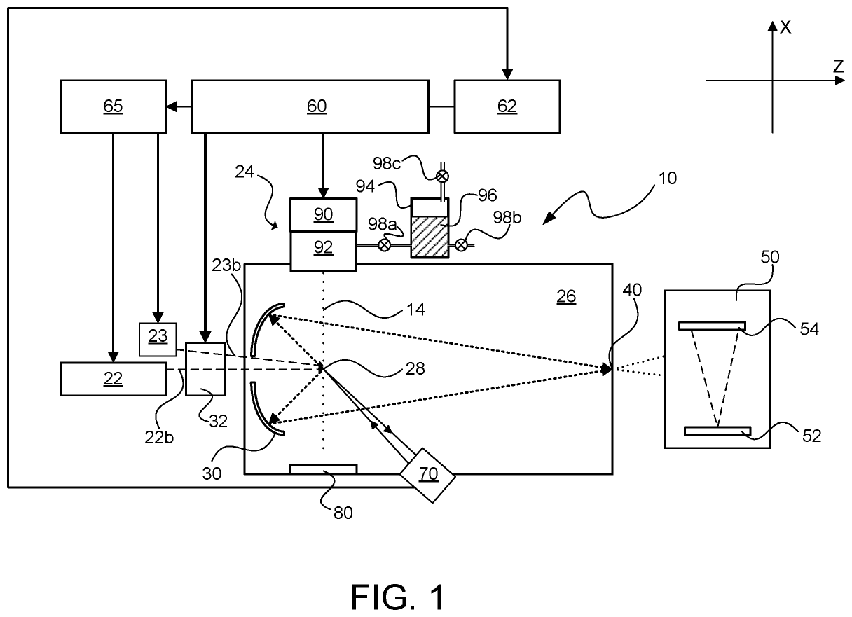

FIG. 1 is a schematic diagram of an example of an EUV radiation source, e.g., a laser produced plasma EUV radiation source 10. As shown, the EUV radiation source 10 may include a pulsed or continuous laser source 22, which may, for example, be a pulsed gas discharge CO₂ laser source producing a beam 22b of pulses of radiation at a wavelength generally below 20 μm, for example, in the range of about 11 μm to about 9 μm or less. The pulsed gas discharge CO₂ laser source may have DC or RF excitation operating at high power and at a high pulse repetition rate.

The EUV radiation source 10 also includes a target material delivery system 24 for delivering target material in the form of liquid droplets or a continuous liquid stream. In this example, the target material is a liquid, but it could also be a solid. The target material may be made up of tin or a tin compound, although other materials could be used. In the system depicted the target material delivery system 24 introduces droplets 14 of the target material into the interior of a vacuum chamber 26 to an irradiation region 28 where the droplets 14 may be irradiated to produce plasma. It should be noted that as used herein an irradiation region is a region where target material irradiation is to occur and is an irradiation region even at times when no irradiation is actually occurring. The EUV light source 10 also includes a beam focusing and steering system 32.

In the example shown, the components are arranged so that the droplets 14 travel substantially horizontally with respect to gravity. The direction from the laser source 22 towards the irradiation region 28, that is, the nominal direction of propagation of the beam 22b, may be taken as the Z axis. The path the droplets 14 take from the target material delivery system 24 to the irradiation region 28 may be taken as the X axis. The view of FIG. 1 is thus normal to the XZ plane. While a system in which the droplets 14 travel substantially horizontally is depicted, it will be understood by one having ordinary skill in the art that other arrangements can be used in which the droplets 14 travel vertically or at some angle with respect to gravity between and including 90 degrees (horizontal) and 0 degrees (vertical).

The EUV radiation source 10 may also include an EUV light source controller system 60 and a laser firing control system 65 along with the beam steering system 32. The EUV radiation source 10 may also include a detector such as a target position detection system which may include one or more droplet imagers 70 that generate an output indicative of the absolute or relative position of a target droplet, e.g., relative to the irradiation region 28, and provide this output to a target position detection feedback system 62. The target position detection feedback system 62 may use the output of the droplet imager 70 to compute a target position and trajectory, from which a target error can be computed.

The EUV radiation source 10 shown in FIG. 1 also includes a conditioning laser 23 for generating a conditioning beam 23b. This conditioning beam 23b is made up of pulses that prepare the target for subsequent heating by the main drive pulse. The conditioning pulse can change the shape or distribution of the target. It includes pulses variously referred to as pre-pulses, pedestal pulses, and rarefication pulses. The laser beam steering system 32 is capable of steering the conditioning beam 23b generated by the conditioning laser 23.

As shown in FIG. 1, the target material delivery system 24 may include a target delivery control system 90. The target delivery control system 90 is operable in response to a signal, for example, a target error or some quantity derived from the target error provided by the system controller 60, to adjust paths of the targets 14 through the irradiation region 28. This may be accomplished, for example, by repositioning the point at which a target delivery mechanism 92 releases the droplets 14. The droplet release point may be repositioned, for example, by tilting or shifting the target delivery mechanism 92.

The target delivery mechanism 92 extends into the chamber 26 and is supplied with target material 96 from a target material reservoir 94. The target material reservoir 94 is in fluid communication with the target delivery mechanism 92 through a reservoir target material outlet valve 98a. The reservoir target material outlet valve 98a may be configured as a freeze valve in which the flow of molten tin is controlled by permitting/causing molten tin to solidify in the valve to close the valve and permitting/causing solid tin to melt in the valve to open the valve. The target material reservoir 94 is also in fluid communication with a source of liquid target material through a reservoir target material inlet valve 98b. The reservoir target material inlet valve 98b may also be configured as a freeze valve. In some embodiments there may be only a single target material conduit permitting adding target material to and withdrawing target material from the target material reservoir 94 and so serving as both an inlet and an outlet.

The liquid target material 96 within the target material reservoir 94 is maintained under pressure by a gas supplied from a gas supply (not shown) in fluid communication with the target material reservoir 94 through a reservoir gas inlet valve 98c.

It will be understood that the EUV radiation source 10 may include more than one target material reservoir 94. The liquid target material 96 within the target material reservoir 94 may be produced by any one of several methods generally involving melting pure solid tin.

The EUV radiation source 10 also includes a target material catch 80 that catches and retains target material which has not been converted through irradiation to limit contamination from such unconverted target material.

Continuing with FIG. 1, the EUV radiation source 10 may also include one or more optical elements. In the following discussion, a collector 30 is used as an example of such an optical element, but the discussion applies to other types of optical elements as well. The collector 30 may be a normal incidence reflector, for example, implemented as a multilayer mirror with additional thin barrier layers, for example B₄C, ZrC, Si₃N₄ or C, deposited at each layer interface to effectively block thermally induced interlayer diffusion. The collector 30 may be in the form of a prolate ellipsoid, with a central aperture to allow the beam 22b and conditioning beam 23b to pass through and reach the irradiation region 28. The collector 30 may have a first focus at the irradiation region 28 and a second focus at an intermediate point 40 (also called the intermediate focus 40) where the EUV radiation may be output from the EUV radiation source 10 and input to, e.g., an integrated circuit lithography scanner or stepper 50. The integrated circuit lithography scanner or stepper 50 uses the radiation, for example, to process a silicon wafer workpiece 52 in a known manner using a reticle or mask 54. The silicon wafer workpiece 52 may then be processed additionally in a known manner to obtain an integrated circuit device.

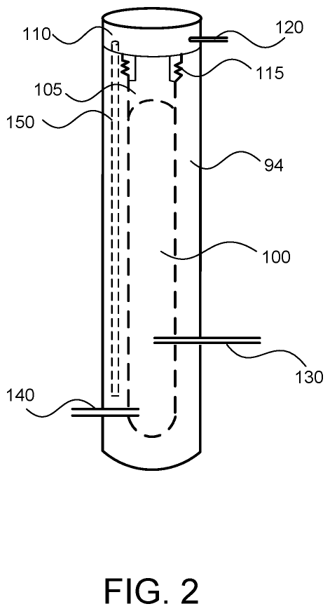

FIG. 2 is a perspective view of a target material storage system with some hidden elements shown by a broken line according to an aspect of an embodiment. As can be seen, the target material storage system includes a target material reservoir 94 having walls defining a reservoir cavity 100 sealed by a reservoir cap 105 secured by a reservoir cap threaded connection 115 described in greater detail below. In some embodiments the target material reservoir 94 is generally cylindrical. The target material storage system of FIG. 2 also includes a reservoir gas cap 110 with a reservoir gas inlet 120 for supplying a gas to the reservoir cavity 100 to place liquid target material in the reservoir cavity 100 under pressure.

The target material storage system of FIG. 2 also includes a reservoir target material inlet 130 for adding liquid target material to the reservoir cavity 100 and a reservoir target material outlet 140 for removing liquid target material from the target material reservoir cavity 100 for supply to target delivery mechanism 92 as described above in connection with FIG. 1. As mentioned, in some embodiments there may be only a single target material conduit permitting adding target material to and withdrawing target material from the target material reservoir 94 and so serving as both an inlet and an outlet.

The target material storage system of FIG. 2 additionally includes a rod heating element 150 for heating the target material reservoir 94. While FIG. 2 shows only one rod heating element 150 it will be understood by one of ordinary skill in the art that in general the target material storage system may include more than one heating element.

As mentioned above, the target material reservoir 94 is made of a material that is resistant to corrosion by exposure to the hot liquid target material 96, for example, tin, in the target material reservoir 94. One suitable choice for the material making up the walls of the target material reservoir 94 when the target material is tin is molybdenum, for example, molybdenum ASTM B387 Type 361 (molybdenum 361) which is 99.9% molybdenum with potassium, aluminum, silicon, iron, nickel, copper, chromium, sodium, and tungsten being present in trace quantities. However, when molybdenum 361 is subjected to various techniques of shaping or forming, the resulting mechanical structure may be anisotropic. For example, work hardening during rolling/forging may, in some situations, cause the material properties of the molybdenum 361 to vary axially and radially for a generally cylindrical hollow target material reservoir.

In accordance with an aspect of an embodiment, at least some components of the target material storage system such as the target material reservoir are made of molybdenum fabricated so that the material properties of the molybdenum are substantially isotropic, e.g., made using a powder metallurgy process, specifically, a hot isostatically pressed (HIP) process that results in the molybdenum being isotropic.

Here and elsewhere in this specification the terms “isotropic” and “substantially isotropic” mean that the material's properties are the same, regardless of the direction in which they are determined, within +/−5%.

HIP is a materials fabrication process in which a starting powder or a premolded shape is simultaneously subjected to both high temperatures and high isostatic pressures. The gas pressure is referred to as being isostatic because it is uniformly applied in all directions. HIP can combine high temperature (e.g., up to and exceeding 2200° C.) and a high isostatic gas pressure (e.g., in a range of 200-500 MPa). The molybdenum starting powder may be produced in a known manner by concentrating molybdenum disulfide (MoS₂) and transforming it to an impure technical molybdenum trioxide (MoO₃) by means of roasting. Subsequent purification takes advantage of the sublimation characteristics of the molybdenum trioxide. See Neikov et al., “Production of Refractory Metal Powders”, Handbook of Non-Ferrous Metal Powders (Second Edition 2019). The molybdenum powder is then compacted and sintered. The resulting blank is then subjected to a HIP process.

The HIP process does not entail any forming-process induced deformation and is capable of producing an isotropic grain structure in the material resulting in isotropic material properties and so can be used to produce isotropic molybdenum.

More information about the application of a HIP process to molybdenum may be found in Barranco et al., “The Densification of Molybdenum and Molybdenum Alloy Powders Using Hot Isostatic Pressing”, Technical Report ARLCB-TR-85025, Accession No. AD-A159 886 (August 1985). Further information may be found in Takida et al., “Mechanical Properties of Fine-Grained, Sintered Molybdenum Alloys with Dispersed Particles Developed by Mechanical Alloying”, Materials Transactions, Vol. 45, No. 1, pp. 143-148 (2004) which describes HIP processing of pure molybdenum. A suitable isostatic molybdenum made using a HIP process is available from Plansee SE, Metallwerk-Plansee-Str. 71, 6600 Reutte, Austria.

In some embodiments the isostatic molybdenum is pure. Here and elsewhere in this specification the term “pure” is intended to connote so-called “three nines” purity, i.e., 99.9% purity by weight. For example, American Society of Mechanical Engineers (ASME) Boiler and Pressure Vessel Codes draft Code Case 3063, “Use of Hot-Isostatically Pressed Pure Isotropic Molybdenum Section VIII, Division 1 and Section VIII, Division 2, Class 1,” approved Dec. 12, 2022 (ASME Code Case 3063), provides that isotropic pure molybdenum powdered metal components produced by HIP may be used for ASME Section VIII Division 1 and Section VIII Division 2 Class 1 construction, subject to certain additional requirements including that the process fluid is limited to molten tin and non-flammable fluids. The chemical composition of the pure molybdenum referenced in ASME Code Case 3063 is required to conform to the chemical composition described below, taken from ASME Code Case 3063:

| Element | Composition (weight )% |
|---|---|
| C, max | 0.010 |
| O, max | 0.0070 |
| N, max | 0.0020 |
| Fe, max | 0.010 |
| Ni, max | 0.005 |
| Si, max | 0.010 |
| Mo | balance |

This molybdenum is “pure” within the meaning of that term in ASME Code Case 3063 as well as in the description and claims herein. It will be understood that other materials such as tungsten may be present in pure molybdenum at or below 0.010 weight percent as well as so-called “inevitable impurities.”

All patent applications, patents, and printed publications cited herein are incorporated herein by reference in their entireties, except for any definitions, subject matter disclaimers, or disavowals, and except to the extent that the incorporated material is inconsistent with the express disclosure herein, in which case the language in this disclosure controls.

In some embodiments the isotropic molybdenum is unalloyed. As used herein, the term “unalloyed” connotes a material in which no additional material has been intentionally or purposefully added to alter a material property. Thus, “unalloyed molybdenum” connotes molybdenum to which no other material has been added to alter the material properties of the molybdenum and may for example include trace amounts of inevitable impurities. It will be apparent to one of ordinary skill in the art that isotropic molybdenum may be both pure and unalloyed.

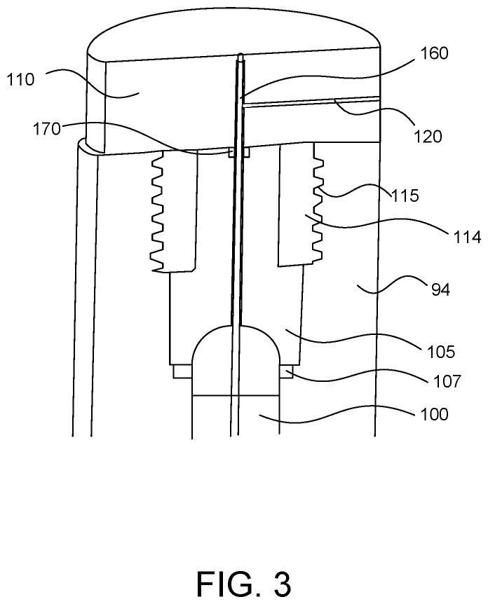

FIG. 3 is an upper portion of a target material storage system according to an aspect of an embodiment. The target material reservoir 94 of FIG. 3 includes, as above, a reservoir cavity 100 which is sealed by a reservoir vessel cap 105. In accordance with an aspect of an embodiment, the reservoir vessel cap 105 is also made from isotropic molybdenum made, for example, using a HIP process. The isotropic molybdenum may be pure or unalloyed or both. The vessel cap 105 engages a reservoir cavity seal 107 to seal the reservoir cavity 100. The vessel cap 105 is retained in place by a locking screw 114 which engages with the reservoir cap threaded connection 115. As shown, in some embodiments the thread profile of the reservoir cap threaded connection 115 may be trapezoidal for increased strength. In accordance with an aspect of an embodiment, the locking screw 114 is also made from isotropic molybdenum which may be made using a HIP process. The isotropic molybdenum may be pure or unalloyed or both.

The portion of the target material storage system of FIG. 3 also includes the reservoir gas cap 110 having the reservoir gas inlet 120 which permits introduction of gas into the cavity 100 to pressurize the reservoir cavity 100. The reservoir gas cap 110 engages a gas cap seal 170. The arrangement FIG. 3 also includes a target material level sensing electrode 160 as described more fully below.

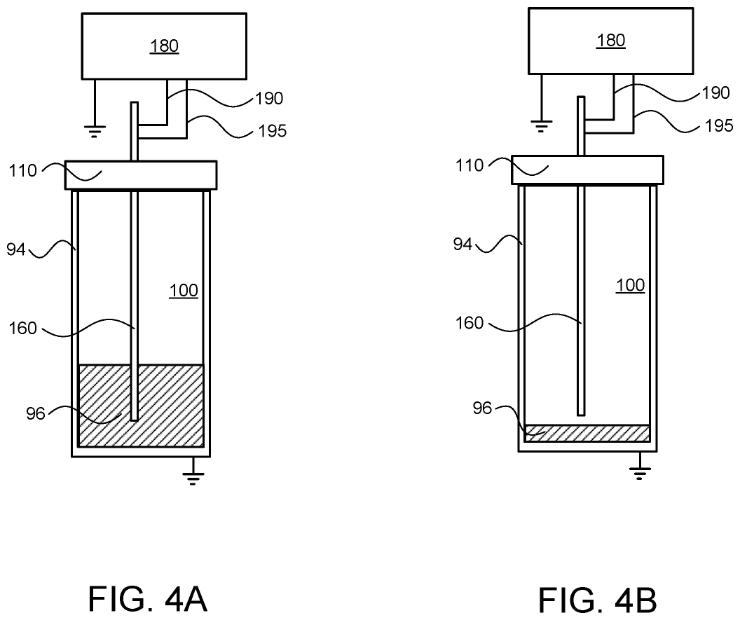

FIGS. 4A and 4B are diagrams elucidating principles of operation of a target material level sensing system in accordance with an aspect of an embodiment. In the case depicted in FIG. 4A the amount of liquid target material 96 in the target material reservoir 94 is sufficient to make contact with the target material level sensing electrode 160. In the embodiment shown the target material reservoir 94 is oriented generally vertically with respect to gravity so that the liquid target material 96 collects at the bottom of the reservoir cavity 100 with a top surface that is essentially horizontal with respect to gravity. The target material sensing electrode 160 is made of a material that is electrically conductive and resistant to corrosion by liquid target material such as, for example, molybdenum when the target material is tin. The target material sensing electrode 160 is in electrical connection with a control module 180 through a first connection 190 which applies an input voltage to the target material level sensing electrode 160. The input voltage may be on the order of, for example, 24 volts DC. The target material level sensing electrode 160 is also in electrical connection with the control module 180 through a line 195 which returns a signal indicating a sensed voltage. In the circumstance depicted in FIG. 4A, the liquid target material 96 in the target material reservoir completes an electrical connection from the target material level sensing electrode 100 to ground (an electrical short) which drives the sensed voltage on line 195 downward.

In the circumstance depicted in the FIG. 4B, on the other hand, the level of liquid target material 96 in the target material reservoir 94 is not high enough to make electrical contact with the target material level sensing electrode 160. The target material level sensing electrode 160 is thus not grounded and its voltage floats. In this case, the sensed voltage on line 195 will be higher. The control module 180 uses the sensed voltage returned to it on line 195 to determine whether the amount of liquid target material 96 in the target material reservoir 94 is below a predetermined level and thus in need of replenishment.

The present disclosure is made with the aid of functional building blocks illustrating the implementation of specified functions and relationships thereof. The boundaries of these functional building blocks have been arbitrarily defined herein to promote clear description. Alternate boundaries can be defined so long as the specified functions are appropriately performed. For example, control module functions can be divided among several systems or performed at least in part by an overall control system.

The above description includes examples of one or more embodiments. It is, of course, not possible to describe every conceivable combination of components or methodologies for purposes of describing the aforementioned embodiments, but one of ordinary skill in the art after being supplied with this disclosure will recognize that many further combinations and permutations of various embodiments are possible. Accordingly, the described embodiments are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated or clear from context. Additionally, all or a portion of any aspect and/or embodiment may be utilized with all or a portion of any other aspect and/or embodiment, unless stated otherwise.

The embodiments can be further described using the following clauses:

1. A target material storage system adapted to store a target material to be irradiated in an extreme ultraviolet radiation source, the target material storage system comprising a reservoir, the reservoir comprising substantially isotropic molybdenum.

2. The target material storage system of clause 1 wherein the substantially isotropic molybdenum is made using a hot isostatic pressing process.

3. The target material storage system of clause 2 wherein the substantially isotropic molybdenum made using a hot isostatic pressing process is pure molybdenum.

4. The target material storage system of clause 2 wherein the substantially isotropic molybdenum made using a hot isostatic pressing process is unalloyed molybdenum.

5. The target material storage system of clause 1 further comprising a vessel cap arranged to seal an upper portion of the reservoir, wherein the vessel cap comprises substantially isotropic molybdenum.

6. The target material storage system of clause 5 wherein the vessel cap comprises isotropic molybdenum made using a hot isostatic pressing process.

7. The target material storage system of clause 5 wherein the vessel cap comprises pure isotropic molybdenum made using a hot isostatic pressing process.

8. The target material storage system of clause 5 wherein the vessel cap comprises unalloyed isotropic molybdenum made using a hot isostatic pressing process.

9. The target material storage system of clause 5 further comprising a locking screw adapted to secure the vessel cap to the reservoir, wherein the locking screw comprises isotropic molybdenum.

10. The target material storage system of clause 9 wherein the locking screw comprises isotropic molybdenum made using a hot isostatic pressing process.

11. The target material storage system of clause 9 wherein the locking screw comprises pure isotropic molybdenum made using a hot isostatic pressing process.

12. The target material storage system of clause 9 wherein the locking screw comprises unalloyed isotropic molybdenum made using a hot isostatic pressing process.

13. A molten tin storage system comprising at least one component which comes into contact with the molten tin, the at least one component comprising isotropic molybdenum.

14. The molten tin storage system of clause 13 wherein the isotropic molybdenum is made using a hot isostatic pressing process.

15. The molten tin storage system of clause 13 wherein the isotropic molybdenum made using a hot isostatic pressing process is unalloyed.

16. The molten tin storage system of clause 13 wherein the at least one component comprises a reservoir defining a cavity adapted to contain the molten tin.

17. The molten tin storage system of clause 16 wherein the at least one component further comprises a vessel cap arranged to seal an upper portion of the reservoir.

18. The molten tin storage system of clause 17 wherein the at least one component further comprises a locking screw adapted to secure the vessel cap to the reservoir.

19. A source of extreme ultraviolet radiation for semiconductor photolithography, the source comprising:
a vacuum chamber;
collector optics arranged within the vacuum chamber and to have a focus within the chamber;
a target material delivery system arranged to dispense droplets of a target material to an irradiation site within the chamber at the focus; and
a target material storage system arranged to provide the target material to the droplet generator, the target material storage system comprising a target material reservoir comprising isotropic molybdenum.

20. The source of clause 19 wherein the isotropic molybdenum is pure and made using a hot isostatic pressing process.

21. The source of clause 19 wherein the target material storage system further comprising a target material level sensing electrode extending into the target material reservoir and adapted to sense a level of target material in the target material reservoir.

The above described implementations and other implementations are within the scope of the following claims.

1. A target material storage system adapted to store a target material to be irradiated in an extreme ultraviolet radiation source, the target material storage system comprising a reservoir, the reservoir comprising substantially isotropic molybdenum.

2. The target material storage system of claim 1 wherein the substantially isotropic molybdenum is made using a hot isostatic pressing process.

3. The target material storage system of claim 2 wherein the substantially isotropic molybdenum made using a hot isostatic pressing process is pure molybdenum.

4. The target material storage system of claim 2 wherein the substantially isotropic molybdenum made using a hot isostatic pressing process is unalloyed molybdenum.

5. The target material storage system of claim 1 further comprising a vessel cap arranged to seal an upper portion of the reservoir, wherein the vessel cap comprises substantially isotropic molybdenum.

6. The target material storage system of claim 5 wherein the vessel cap comprises isotropic molybdenum made using a hot isostatic pressing process.

7. The target material storage system of claim 5 wherein the vessel cap comprises pure isotropic molybdenum made using a hot isostatic pressing process.

8. The target material storage system of claim 5 wherein the vessel cap comprises unalloyed isotropic molybdenum made using a hot isostatic pressing process.

9. The target material storage system of claim 5 further comprising a locking screw adapted to secure the vessel cap to the reservoir, wherein the locking screw comprises isotropic molybdenum.

10. The target material storage system of claim 9 wherein the locking screw comprises isotropic molybdenum made using a hot isostatic pressing process.

11. The target material storage system of claim 9 wherein the locking screw comprises pure isotropic molybdenum made using a hot isostatic pressing process.

12. The target material storage system of claim 9 wherein the locking screw comprises unalloyed isotropic molybdenum made using a hot isostatic pressing process.

13. A molten tin storage system comprising at least one component which comes into contact with the molten tin, the at least one component comprising isotropic molybdenum.

14. The molten tin storage system of claim 13 wherein the isotropic molybdenum is made using a hot isostatic pressing process.

15. The molten tin storage system of claim 13 wherein the isotropic molybdenum made using a hot isostatic pressing process is unalloyed.

16. The molten tin storage system of claim 13 wherein the at least one component comprises a reservoir defining a cavity adapted to contain the molten tin.

17. The molten tin storage system of claim 16 wherein the at least one component further comprises a vessel cap arranged to seal an upper portion of the reservoir.

18. The molten tin storage system of claim 17 wherein the at least one component further comprises a locking screw adapted to secure the vessel cap to the reservoir.

19. A source of extreme ultraviolet radiation for semiconductor photolithography, the source comprising:
a vacuum chamber;
collector optics arranged within the vacuum chamber and to have a focus within the chamber;
a target material delivery system arranged to dispense droplets of a target material to an irradiation site within the chamber at the focus; and
a target material storage system arranged to provide the target material to the droplet generator, the target material storage system comprising a target material reservoir comprising isotropic molybdenum.

20. The source of claim 19 wherein the isotropic molybdenum is pure and made using a hot isostatic pressing process.

21. The source of claim 19 wherein the target material storage system further comprising a target material level sensing electrode extending into the target material reservoir and adapted to sense a level of target material in the target material reservoir.
